(19) United States
(12) Patent Application Publication
(10) Pub. No.: US 2025/0310687 A1
(43) Pub. Date: Oct. 2, 2025

(54) DRIVE CIRCUIT AND ELECTRO-ACOUSTIC CONVERSION SYSTEM

(71) Applicants: Yuji KIMURA, Tokyo (JP); Maiko NAGAWATARI, Tokyo (JP); Motoki KOMATSU, Tokyo (JP)

(72) Inventors: Yuji KIMURA, Tokyo (JP); Maiko NAGAWATARI, Tokyo (JP); Motoki KOMATSU, Tokyo (JP)

(73) Assignee: MITSUMI ELECTRIC CO., LTD., Tokyo (JP)

(21) Appl. No.: 19/070,949

(22) Filed: Mar. 5, 2025

(30) Foreign Application Priority Data
Mar. 26, 2024 (JP) 2024-049447
Mar. 26, 2024 (JP) 2024-049448

(51) Int. Cl. H04R 3/04; H03F 3/183; H04R 17/00

(52) U.S. Cl. CPC H04R 3/04; H03F 3/183; H04R 17/00; H03F 2200/03; H04R 2201/003

(57) ABSTRACT

A drive circuit includes an amplifier configured to amplify an input signal, and supply the amplified input signal as a drive signal to a piezoelectric element of a MEMS (Miro-Electro-Mechanical Systems) speaker driven by a piezoelectric element; and an offset generator configured to generate an offset such that a minimum absolute value of a voltage of the drive signal is greater than or equal to a positive predetermined voltage.

### CROSS-REFERENCE TO RELATED APPLICATIONS

This application claims priority under 35 U.S.C. § 119 to Japanese Patent Application Nos. 2024-049447, filed Mar. 26, 2024, and 2024-049448, filed Mar. 26, 2024, the contents of which are incorporated herein by reference.

### BACKGROUND

### 1. Technical Field

The present disclosure relates to a drive circuit and an electro-acoustic conversion system.

### 2. Description of the Related Art

A speaker using MEMS (Micro Electro Mechanical Systems) is known as an electro-acoustic converter. It is known that a piezoelectric element is used as a drive unit of the MEMS (for example, Patent Document 1).

### RELATED-ART DOCUMENT

### Patent Document

Patent Document 1: Japanese Patent No. 7157332

### SUMMARY

A piezoelectric body of a piezoelectric element is polarized by applying a DC voltage to the piezoelectric body. The piezoelectric body maintains a polarized state even after the DC voltage applied to the piezoelectric body is removed. In this case, piezoelectric characteristics of the piezoelectric body can be maintained at a high level. When a voltage is applied to the piezoelectric body in a direction opposite to the polarization, depolarization occurs, in which a polarized state disappears. In order to suppress the depolarization of the piezoelectric body, a positive drive signal is supplied to the piezoelectric element. However, when noise or the like is added to the drive signal, a negative voltage is applied to the piezoelectric element, and thus the piezoelectric element may deteriorate.

The present disclosure provides a drive circuit and an electro-acoustic conversion system capable of suppressing deterioration of a piezoelectric element.

In an embodiment of the present disclosure, a drive circuit includes an amplifier configured to amplify an input signal, and supply the amplified input signal as a drive signal to a piezoelectric element of a MEMS (Miro-Electro-Mechanical Systems) speaker by the driven piezoelectric element; and an offset generator configured to generate an offset such that a minimum absolute value of a voltage of the drive signal is greater than or equal to a positive predetermined voltage.

In the present disclosure, deterioration of a piezoelectric element can be suppressed.

### BRIEF DESCRIPTION OF THE DRAWINGS

FIG. 1 is a block diagram of an electro-acoustic conversion system according to a first embodiment.

FIG. 2 is a plan view of a MEMS speaker according to the first embodiment.

FIGS. 3A and 3B are diagrams showing voltages of drive signals with respect to time in a comparative configuration.

FIG. 3C is a diagram showing a voltage of a drive signal with respect to time according to the first embodiment.

FIGS. 4A, 4B, and 4C are circuit diagrams of circuits 30, 31, and 32, respectively.

FIGS. 5A, 5B, and 5C are diagrams showing voltages with respect to time in the circuits 30, 31, and 32, respectively.

FIG. 6 is a block diagram of the electro-acoustic conversion system according to a second embodiment.

FIG. 7 is a block diagram of a drive circuit according to the second embodiment.

FIG. 8 is a block diagram of the drive circuit in a first comparative example.

FIGS. 9A and 9B are diagrams showing voltages with respect to time for describing the operation of a class-A or class-B amplifier and a class-H amplifier.

FIGS. 10A and 10B are diagrams showing voltages with respect to time in the first comparative example.

FIG. 11 is a block diagram of the drive circuit in a second comparative example.

FIGS. 12A to 12D are diagrams showing voltages with respect to time in the first comparative example.

FIGS. 13A and 13B are diagrams showing voltages with respect to time in the second comparative example.

FIG. 14 is a block diagram of the drive circuit according to a third embodiment.

FIG. 15 is a block diagram of the electro-acoustic conversion system according to the third embodiment.

### DETAILED DESCRIPTION

Various embodiments of the present disclosure will be described below in detail with reference to the drawings. The following embodiments are examples to embody a technical concept of the present disclosure, and the present disclosure is not limited to the configurations and numerical values described below. In each of the drawings, the same numerals may denote the same components, and redundant description may be omitted as appropriate. The sizes, positional relationship, and the like of components shown in each of the drawings may be exaggerated to facilitate understanding of the present disclosure.

### First Embodiment

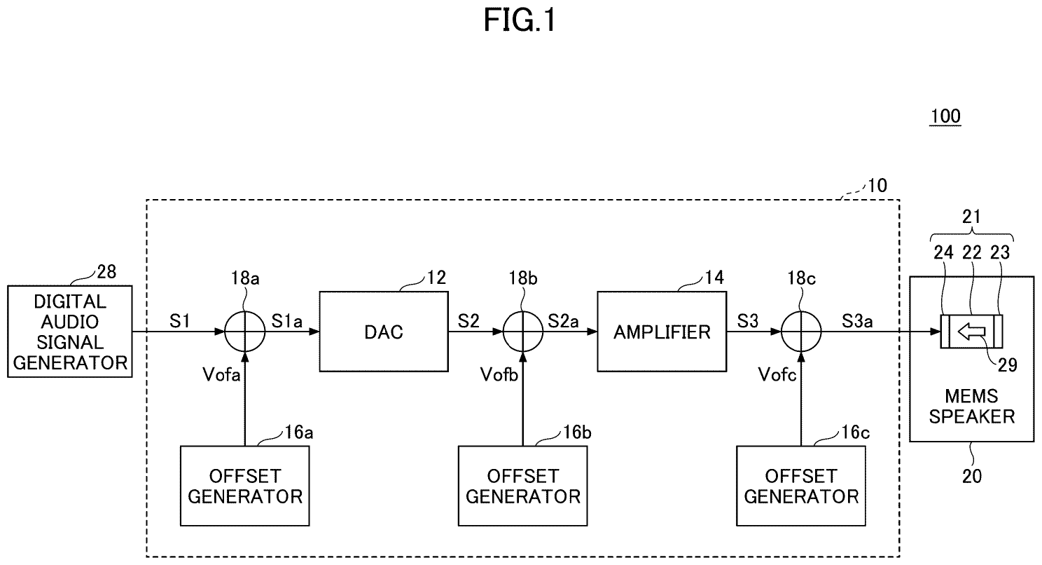

FIG. 1 is a block diagram of an electro-acoustic conversion system according to a first embodiment. An electro-acoustic conversion system 100 according to the first embodiment includes a drive circuit 10 and a MEMS speaker 20. The electro-acoustic conversion system 100 receives a digital audio signal S1 from a digital audio signal generator 28.

The drive circuit 10 includes a DAC (Digital-to-Analog Converter) 12, an amplifier 14, offset generators 16a to 16c, and adders 18a to 18c. The DAC 12 may be provided outside the drive circuit 10. The drive circuit 10 may include at least one set of: a set of an offset generator 16a and an adder 18a, a set of an offset generator 16b and an adder 18b, or a set of an offset generator 16c and an adder 18c.

The DAC 12 converts the digital signal S1 or a digital signal Sla into an analog signal S2. The amplifier 14 amplifies the analog signal S2 or an analog signal S2a, and outputs the amplified signal as a signal S3. The amplifier 14 is, for example, an audio amplifier or a piezo driver. The signal S3 or a signal S3a is output to the MEMS speaker 20.

The offset generator 16a generates an offset value Vofa, which is a digital value. The adder 18a adds the offset value Vofa to the digital signal S1, and outputs the signal S1 to which the offset value Vofa is added as the digital signal Sla to the DAC 12. If the set of the offset generator 16a and the adder 18a is not provided, the signal S1 is input to the DAC 12.

The offset generator 16b generates an offset voltage Vofb. The adder 18b adds the offset voltage Vofb to the signal S2, and outputs the signal S2 to which the offset voltage Vofb is added as the signal S2a to the amplifier 14. If the set of the offset generator 16b and the adder 18b is not provided, the signal S2 is input to the amplifier 14.

The offset generator 16c generates an offset voltage Vofc. The adder 18c adds the offset voltage Vofc to the signal S3, and outputs the signal S3 to which the offset voltage Vofc is added as the drive signal S3a to at least one piezoelectric element 21 in the MEMS speaker 20. If the set of the offset generator 16c and the adder 18c is not provided, the signal S3 is supplied as the drive signal to the piezoelectric element 21.

In FIG. 1, the offset generators 16a to 16c and the adders 18a to 18c are shown separately for the purpose of describing their functions. However, in an actual generators 16a to 16c and their circuit, the offset corresponding adders 18a to 18c may be integrally formed as offset generators 16a to 16c.

The MEMS speaker 20 is an electro-acoustic transducer using MEMS, and is an earpiece or a built-in speaker. The MEMS speaker 20 includes the piezoelectric element 21 that drives the MEMS speaker 20. The piezoelectric element 21 includes a piezoelectric body 22, and electrodes 23 (first electrode) and 24 (second electrode) for applying a voltage to the piezoelectric body 22. The piezoelectric body 22 is spontaneously polarized (arrow 29) such that the direction from the electrode 23 to the electrode 24 is positive. The drive signal S3 or S3a is supplied to the piezoelectric element 21 such that a positive voltage is applied to the electrode 24 with respect to the electrode 23.

### (Description of MEMS Speaker)

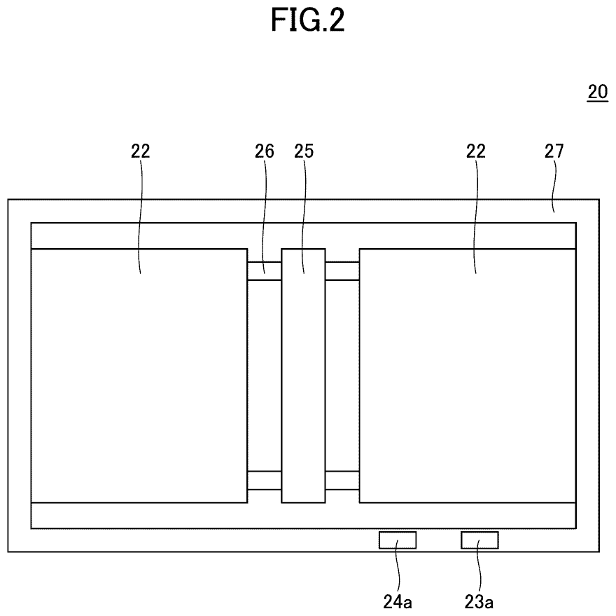

FIG. 2 is a plan view of the MEMS speaker according to the first embodiment. As shown in FIG. 2, the MEMS speaker includes piezoelectric bodies 22, a movable portion 25, a plurality of torsion bars 26, a a fixed frame 27, and electrodes 23a and 24a. The fixed frame 27 is a rigid frame. The planar shape of the fixed frame 27 can be appropriately set as rectangular, polygonal, circular, or elliptical. The movable portion 25 is provided within the fixed frame 27. The planar shape of the movable portion 25 can be appropriately set as rectangular, polygonal, circular, or elliptical. The movable portion 25 is provided with the torsion bars 26. Each of the torsion bars 26, and the fixed frame 27 are connected via a corresponding piezoelectric body among the piezoelectric bodies 22.

The fixed frame 27 is provided with the electrodes 23a and 24a. The electrodes 23a and 24a are electrically connected to the respective electrodes 23 and 24 (see FIG. 1) of each piezoelectric element via one or more wirings provided in the fixed frame 27, where the electrodes 23 and 24 of each piezoelectric element are in contact with a corresponding piezoelectric body 22. When the voltage is applied between the electrodes 23a and 24a, the voltage is applied between the electrodes 23 and 24. As a result, the piezoelectric body 22 is distorted by a reverse piezo effect, and the movable portion 25 is driven. A drive amount of the movable portion 25 varies depending on a voltage value between the electrodes 23 and 24. When the signal S3 or S3a is applied between the electrodes 23 and 24, the movable portion 25 is driven, and sound is output from the MEMS speaker 20. The movable portion 25, the torsion bars 26, and the fixed frame 27 are formed of, for example, a silicon substrate.

The MEMS speaker 20 is manufactured using a semiconductor process, and has the reduced performance variation while achieving compact size, a thin body, light weight, and low power consumption. Moreover, a frequency characteristic of the MEMS speaker 20 is flat up to the mid and high ranges. In the MEMS speaker 20, after the MEMS speaker 20 is manufactured using the semiconductor process, each piezoelectric body 22 is spontaneously polarized by applying a DC voltage to the piezoelectric body of the piezoelectric element 21. Even after the DC voltage applied to the piezoelectric body 22 is removed, the piezoelectric body 22 maintains a polarization state. In this arrangement, a piezoelectric characteristic of each piezoelectric body 22 can be maintained at a high level. However, when a voltage is applied to the piezoelectric body 22 in an opposite direction to the spontaneous polarization, the spontaneous polarization disappears. This is referred to as depolarization.

Such a characteristic is particularly significant when a piezoelectric body having a perovskite crystal structure is used as the piezoelectric body 22. Examples of the piezoelectric body having the perovskite crystal structure may include PZT (lead zirconate titanate), PNZT (lead zirconate niobate titanate), PLZT (lead lanthanum zirconate titanate), PLT (lead lanthanum titanate), PMN (lead magnesium niobate), PMNN (lead manganate niobate), and BaTiO₃ (barium titanate).

The structure of the MEMS speaker 20 shown in FIG. 2 is an example. For the MEMS speaker 20 with one or more piezoelectric elements 21, and any structure in which the piezoelectric elements 21 drive the movable portion 25 may be adopted.

### (Comparative Configuration)

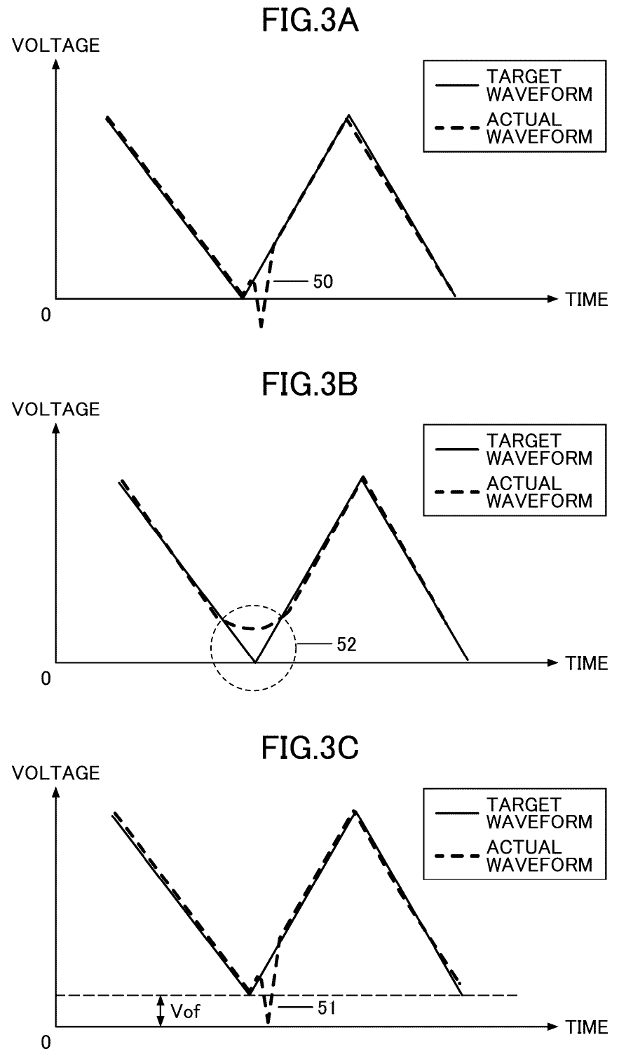

A comparative configuration in which the offset generators 16a to 16c and the adders 18a to 18c are not provided will be described below. FIGS. 3A and 3B are diagrams showing voltages of drive signals with respect to time in the comparative configuration, and FIG. 3C is a diagram showing the voltage of the drive signal with respect to time in the first embodiment. In each of FIGS. 3A to 3C, a target waveform of the drive signal S3 is shown by a solid line, and an actual waveform of the drive signal S3 is shown by a dashed line.

As shown in FIG. 3A, the target waveform is a waveform whose minimum value is 0 V. In this case, depolarization of the piezoelectric body 22 of the piezoelectric element 21 is suppressed. However, due to the effects of noise, in the actual waveform, there is a possibility that noise 50 whose voltage is negative enters a signal. Even if a negative voltage is applied to the piezoelectric element 21 for a short time, it is unlikely that the piezoelectric body 22 depolarizes immediately. However, if the level of the noise 50 exceeds a predetermined level, it may adversely affect the polarization state of the piezoelectric body 22.

As shown in FIG. 3B, linearity may deteriorate around 0 V depending on the type of the amplifier 14. As a result, the actual waveform becomes distorted as shown in a dashed circle 52. In this case, all unnecessary harmonic distortion, including second-order distortion and third-order distortion, occurs in the signal S3. Furthermore, intermodulation distortion may occur. This may result in degradation in sound quality of the MEMS speaker 20.

### First Embodiment

As shown in FIG. 3C, in the first embodiment, the offset generators 16a to 16c generate offset voltages Vof such that a minimum absolute value of the voltage of the drive signal S3 or S3a is equal to or greater than a positive predetermined voltage. In this case, a minimum value of the target waveform becomes the offset voltage Vof. As a result, even if the noise 51 enters the signal, a negative voltage can be suppressed. Therefore, the negative influence of the noise 51 on the polarization state of the piezoelectric body 22 can be suppressed.

Also, a voltage range with good linearity of the amplifier 14 can be used. In this case, waveform distortion can be suppressed even near the minimum voltage. In this arrangement, all harmonic distortion and the like can be suppressed, thereby improving the sound quality of the MEMS speaker 20.

The offset generator 16c may add an offset to the drive signal S3 after amplification by the amplifier 14. The offset generator 16b may add an offset to the input signal S2 before amplification by the amplifier 14. The offset generator 16a may add an offset to the digital signal S1.

When noise occurs in the amplifier 14, it is effective to use the offset generator 16c. From the viewpoint of distortion in the amplifier 14, it is effective when at least one of the offset generators 16a or 16b is used.

In FIG. 3C, preferably, the magnitude of the offset voltage Vof is set such that the noise 51 does not become negative and remains within a range in which distortion of the amplifier 14 is not significant. From this viewpoint, the offset voltage Vof is preferably 0.1% or more of the maximum value of the target waveform, and more preferably 1% or more. If the offset voltage Vof is too large, a dynamic range becomes smaller. From this viewpoint, the offset voltage Vof is preferably 10% or less of the maximum value of the target waveform. As an example, when the maximum value of the target waveform is 30 V, the offset voltage Vof is 2 V.

### Circuit Examples of Offset Generators 16b and 16c

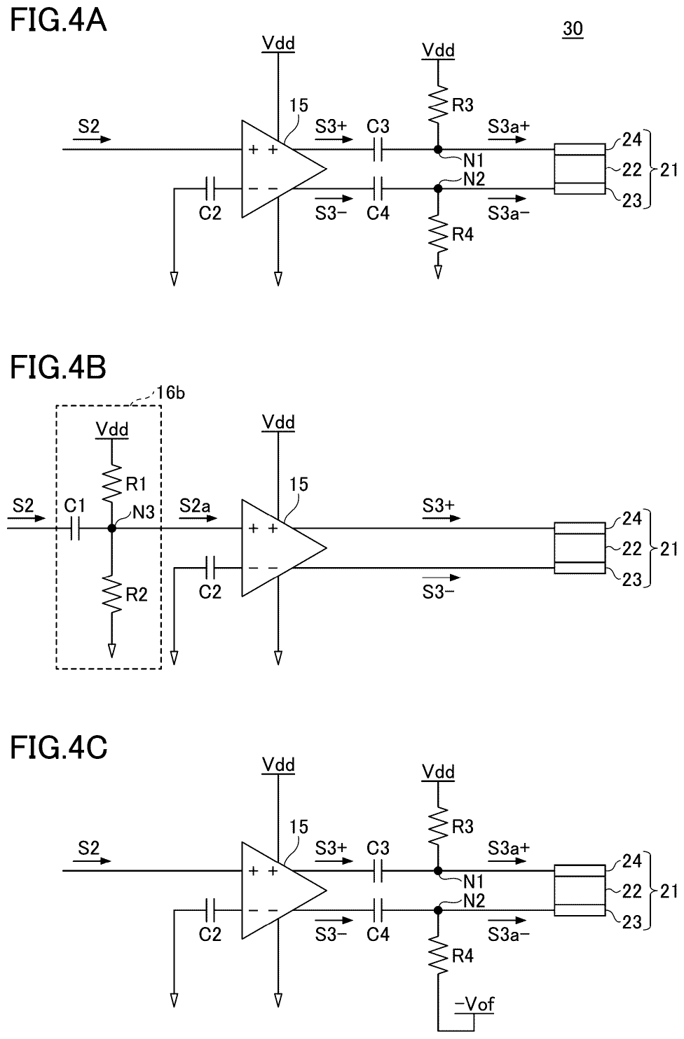

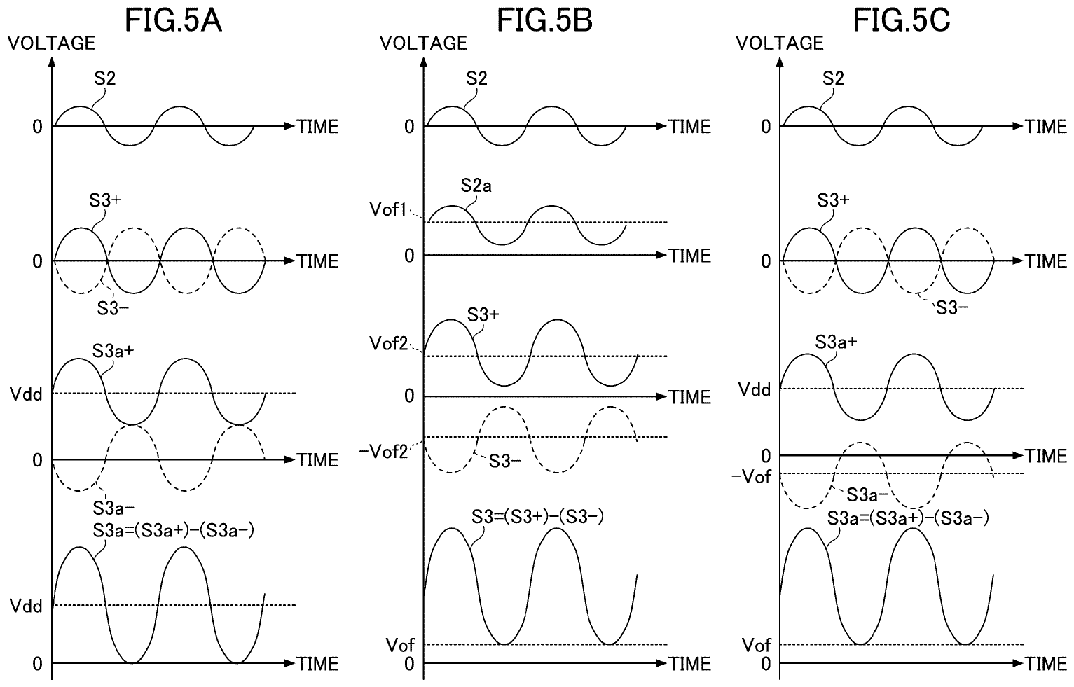

Hereinafter, a circuit 30 having a comparative configuration without the offset generators 16b and 16c will be described. FIG. 4A is a circuit diagram of the circuit 30. FIG. 5A is a diagram showing the voltage with respect to time in the circuit 30.

As shown in FIG. 4A, the circuit 30 includes an amplifier 15, capacitors C2 to C4, and resistors R3 and R4. The amplifier 15 is a differential-input and differential-output amplifier. A power supply voltage Vdd is supplied to the amplifier 15 with respect to ground. The signal S2 is applied to a positive input terminal of the amplifier 15. A negative input terminal of the amplifier 15 is grounded through a capacitor C2. A positive output terminal of the amplifier 15 is electrically connected to the electrode 24 of the piezoelectric element 21 through a capacitor C3. A negative output terminal of the amplifier 15 is electrically connected to the electrode 23 through a capacitor C4.

The power supply voltage Vdd is supplied to a node N1 between the capacitor C3 and the electrode 24 via the resistor R3. A node N2 between the capacitor C4 and the electrode 23 is grounded via the resistor R4. The capacitors C2 to C4 are coupling capacitors for AC signals. The resistance values of the resistors R3 and R4 are sufficiently low compared to the impedance of the piezoelectric element 21, and these resistance values have magnitudes that prevent signals S3a+ and S3a− from leaking to power supply and ground.

As shown in FIG. 5A, the signal S2 is a signal centered at 0 V. The amplifier 15 amplifies the voltage of the signal S2 that is input to the positive input terminal with respect to 0 V at the negative input terminal, and respectively outputs the signal S3+ and the signal S3− to the positive output terminal and the negative output terminal. Each of the signals S3+ and S3− is a signal centered at 0 V, and the maximum amplitude of the signals S3+ and S3− is defined as Vdd. The signal S3− is an inverted signal of the signal S3+.

The voltage at the node N1 is pulled up to Vdd, and the voltage at the node N2 is pulled down to 0 V. As a result, the signal S3a+ becomes a signal centered at Vdd, and the signal S3a− becomes a signal centered at 0 V.

A voltage, (S3a+)-(S3a−), of the drive signal S3a that is applied to the electrode 24 of the piezoelectric element 21 with respect to the electrode 23 becomes a signal centered at Vdd, and a minimum value of the drive signal S3a is 0 V. In this arrangement, the minimum value of the drive signal S3a becomes 0 V.

Hereinafter, a circuit 31 provided with the offset generator 16b will be described. FIG. 4B isa circuit diagram of the circuit 31. FIG. 5B is a diagram showing the voltage with respect to time in the circuit 31.

As shown in FIG. 4B, in the circuit 31, the input signal S2 is input to the positive input terminal of the amplifier 15 via the offset generator 16b. The offset generator 16b includes a capacitor C1 and resistors R1 and R2. The power supply voltage Vdd is applied to a node N3 between the capacitor C1 and the positive input terminal of the amplifier 15 via the resistor R1, and the node N3 is grounded via the resistor R2. The capacitor C1 is a coupling capacitor for an AC signal. The resistance values of the resistors R1 and R2 are sufficiently low compared to the input impedance of the positive input terminal of the amplifier 15, and these resistance values have magnitudes that prevent the signal S2 from leaking to the power supply and the ground. The positive output terminal of the amplifier 15 is electrically connected to the electrode 24 of the piezoelectric element 21. The negative output terminal of the amplifier 15 is electrically connected to the electrode 23. The rest of the components are the same as those in the circuit 30, and description thereof is omitted.

A bias voltage at the node N3 is obtained by dividing the power supply voltage Vdd through the resistors R1 and R2. The resistance values of the resistors R1 and R2 are set such that the bias voltage at the node N3 becomes the offset voltage Vof1. As shown in FIG. 5B, the signal S2a is a signal centering at the offset voltage Vof1. A minimum voltage of the signal S2a is positive.

The signal S3+ is a signal centering at the offset voltage Vof2, and the signal S3− is a signal centering at the offset voltage-Vof2. A minimum voltage of the signal S3+ is positive, and a maximum voltage of the signal S3− is negative.

A minimum value of a voltage, (S3+)-(S3−), of the drive signal S3 that is applied to the electrode 24 of the piezoelectric element 21 with respect to the electrode 23 becomes Vof, which is approximately expressed by 2×Vof2, which. In this arrangement, the minimum value of the drive signal S3 can be set to a positive voltage Vof. Hereinafter, a circuit 32 provided with the offset generator 16c will be described. FIG. 4C is a circuit diagram of the circuit 32. FIG. 5C is a diagram showing the voltage with respect to time in the circuit 32.

As shown in FIG. 4C, in the circuit 32, an offset voltage Vof is applied to the node N2 via the resistor R4. The rest of the components are the same as those in the circuit 30, and description thereof will be omitted.

As shown in FIG. 5C, the signal S3a− is a signal centered at the offset voltage Vof. A minimum value of a voltage, (S3a+)-(S3a−), of the drive signal S3a that is applied to the electrode 24 with respect to the electrode 23 of the piezoelectric element 21 becomes the offset voltage Vof. In this arrangement, the minimum value of the drive signal S3a can be set to a positive voltage Vof.

The circuits 31 and 32 are examples, and other circuit configurations may be used as long as the minimum value of the drive signal S3a can be set to the positive offset voltage Vof. For example, the offset generator 16b may set the bias voltage at the node N3 to Vof1, without using the resistor R1 or R2.

In the offset generator 16c, it is not necessary to use the resistor R3 to pull up the voltage at the node N1, and it is not necessary to use the resistor R4 to pull down the voltage at node N2. The voltage at the node N1 may be pulled up to Vdd+Vof, and the voltage at the node N2 may be pulled down to 0 V. The amplifier 15 may output the signal S3 with respect to the ground, instead of the differential output, and further the electrode 23 may be grounded.

### Second Embodiment

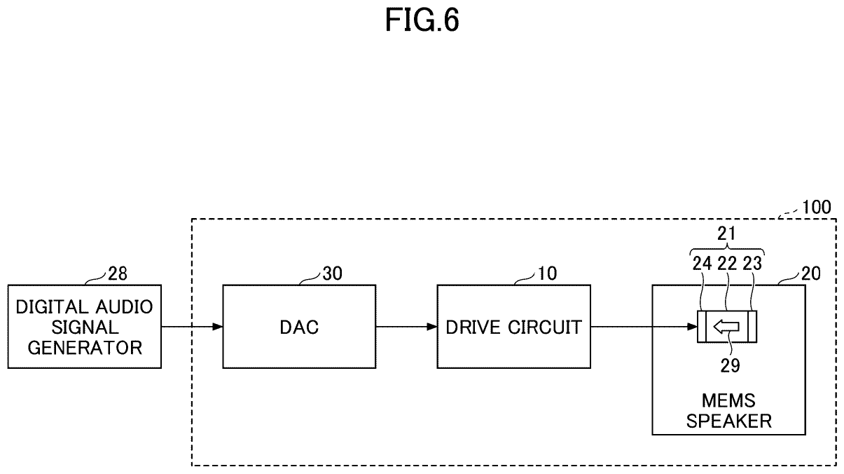

FIG. 6 is a block diagram of the electro-acoustic conversion system according to a second embodiment. An electro-acoustic conversion system 100 according to the second embodiment includes a digital analog converter (DAC) 30, a drive circuit 10, and a MEMS speaker 20. The electro-acoustic conversion system 100 receives an audio digital signal from a digital audio signal generator 28.

The DAC 30 converts an input digital signal into an analog signal. The drive circuit 10 amplifies the analog signal, and outputs an amplified drive signal to the MEMS speaker 20. The drive circuit 10 is, for example, an audio amplifier or a piezo driver.

### (Drive Circuit)

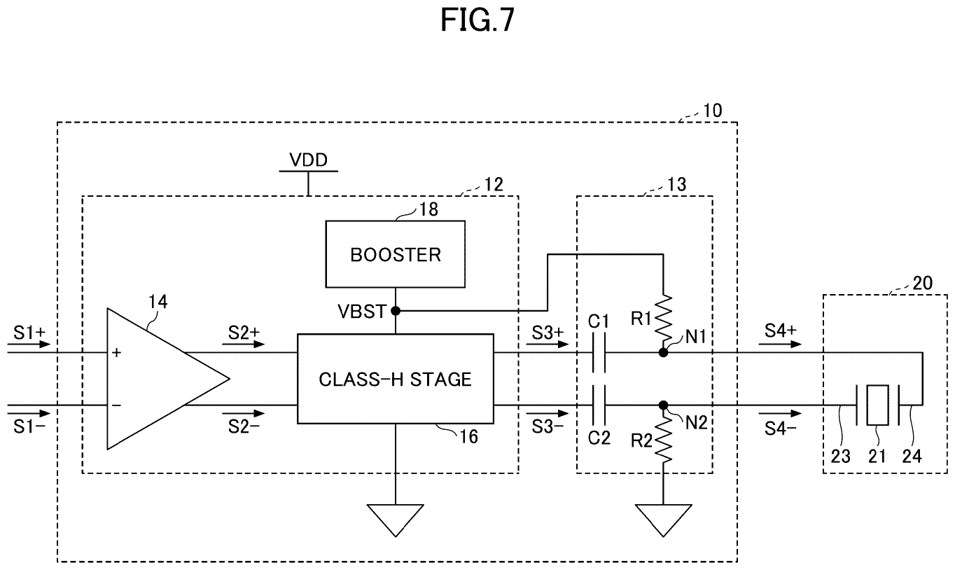

FIG. 7 is a block diagram of the drive circuit according to the second embodiment. As shown in FIG. 7, the drive circuit 10 includes an amplifier 12 and a pull-up circuit 13. The amplifier 12 is a class-H amplifier. The amplifier 12 includes a pre-stage amplifier 14, a class-H stage 16, and a booster 18. The pre-stage amplifier 14 and the class-H stage 16 are differential-input and differential-output amplifiers. The booster 18 supplies a voltage VBST as a power supply voltage to the class-H stage 16.

The pre-stage amplifier 14 differentially amplifies differential signals S1+ and S1− that are input signals, and outputs the amplified signals as differential signals S2+ and S2−. The class-H stage 16 differentially amplifies the differential signals S2+ and S2− while using a voltage VBST as a power supply voltage, and then outputs the amplified signals as differential signals S3+ and S3−.

The pull-up circuit 13 includes capacitors C1 and C2 and resistors R1 and R2. A positive output terminal of the amplifier 12 is electrically connected to an electrode 24 of a piezoelectric element 21 via the capacitor C1. A negative output terminal of the amplifier 12 is electrically connected to an electrode 23 via the capacitor C2. The voltage VBST is applied to a node N1 between the capacitor C1 and the electrode 24 via the resistor R1. A node N2 between the capacitor C2 and the electrode 23 is grounded via the resistor R2. The capacitors C1 and 2 are coupling capacitors for AC signals. Resistance values of the resistors R1 and R2 are sufficiently low compared to the impedance of the piezoelectric element 21, and these resistance values have the magnitudes that prevent the signals S3+ and S3− from leaking to the power supply and the ground. The voltage at the node N1 is pulled up to the voltage VBST, and the voltage at the node N2 is pulled down to a ground potential. Signals S4+ and S4− at the nodes N1 and N2 are supplied to the electrodes 24 and 23, respectively. In this arrangement, the pull-up circuit 13 pulls up an output signal (S3+)-(S3−) output from the amplifier 12 to the voltage VBST, and supplies a pulled-up signal (S4+)-(S4−) to the piezoelectric element 21 as a drive signal.

### First Comparative Example

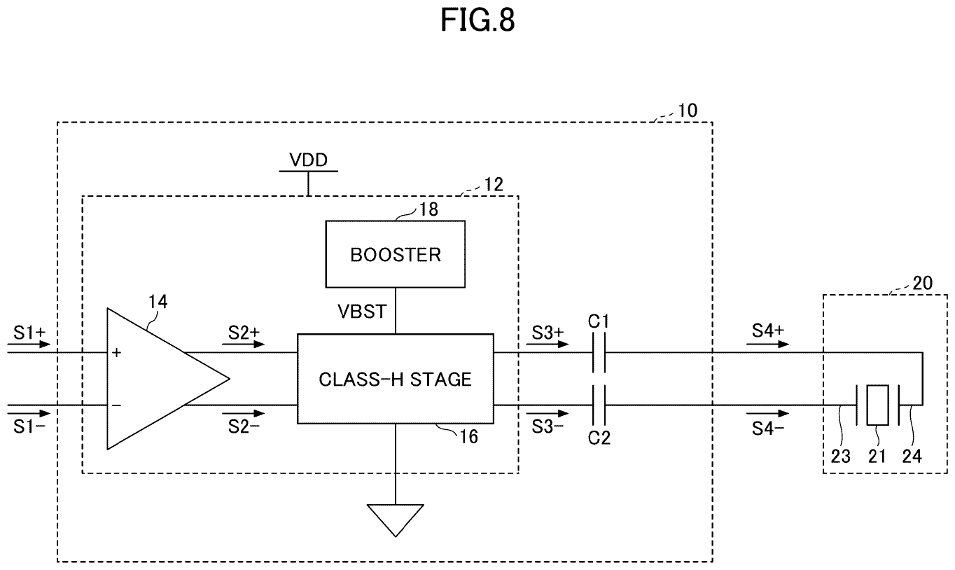

FIG. 8 is a block diagram of the drive circuit in a first comparative example. In the first comparative example, pull-up resistors R1 and R2 are not provided. Other configurations are the same as those of the first embodiment.

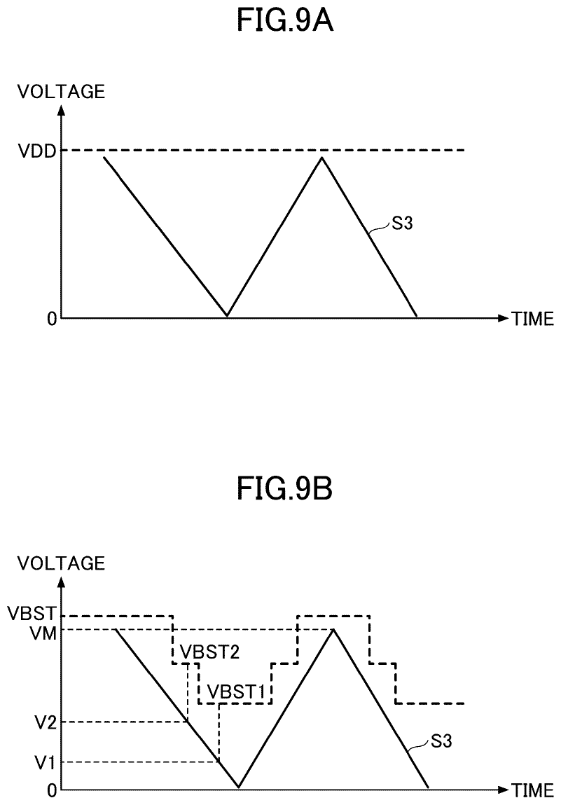

FIGS. 9A and 9B are diagrams showing voltages with respect to time for describing the operation of a class-A or a class-B amplifier and the class-H amplifier. FIG. 9A shows the waveform of an output signal V3 of the class-A or the class-B amplifier, and the power supply voltage for a last stage when the last stage is the class-A or the class-B amplifier. As shown in FIG. 9A, in the class-A or the class-B amplifier, the last stage performs amplification while using VDD defined as the power supply voltage. The waveform of the signal S3 is from 0 V to VDD.

FIG. 9B shows the waveform of the output signal V3 from the class-H stage 16 that is the class-H amplifier, and the power supply voltage. As shown in FIGS. 8 and 9B, in the class-H amplifier, the class-H stage 16 amplifies the power supply voltage while using the voltage VBST output from the booster 18. The booster 18 generates the voltage VBST based on the waveform of the signal S1, S2, or S3. For example, the booster 18 predicts the waveform of the signal S3 from past waveforms, and generates the voltage VBST. As a result, when the voltage of the signal S3 is high, the voltage VBST becomes high, and when the voltage of the signal S3 is low, the voltage VBST becomes low.

For example, a voltage V1 (first voltage), and a voltage V2 (second voltage) higher than voltage V1 are each assumed as the voltage of the signal S3. In this case, a pull-up voltage VBST1 at the voltage V1 is lower than a VBST2 at the voltage V2. In this pull-up voltage arrangement, the pull-up voltage VBST can be changed based on the voltage of the signal S3. In this description, the voltages V1 and V2 are assumed as discussed above. However, it is sufficient if the above-described relationship is defined between the voltage of the signal S3 and the pull-up voltage VBST at any two different time points. In FIG. 9B, three voltage levels are set for the pull-up voltage VBST, but four or more voltage levels for the pull-up voltage VBST may be set.

In addition, a pull-up voltage VBST1 at the voltage V1 is set within a range of lower than a maximum voltage VM and equal to or higher than the voltage V1 in the voltage waveform of the signal S3. A pull-up voltage VBST2 at the voltage V2 is set within a range of lower than the maximum voltage VM and equal to or higher than the voltage V2 in the voltage waveform of the signal S3. In this arrangement, power consumption can be suppressed.

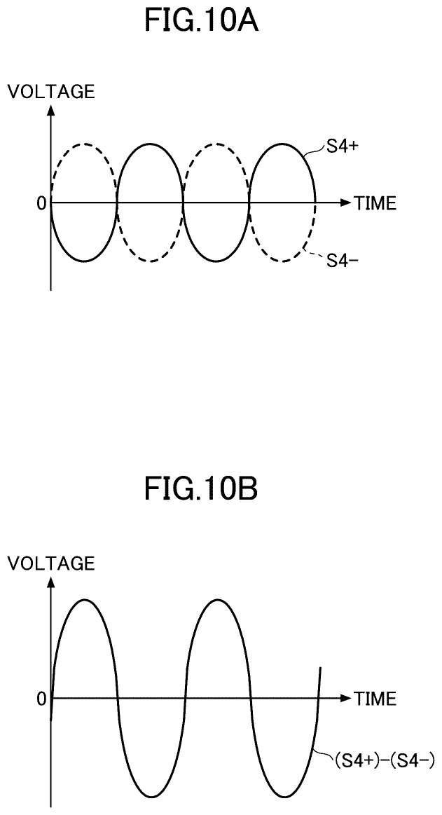

FIGS. 10A and 10B show voltages with respect to time in the first comparative example. The output signals S3+ and S3− of the class-H stage 16 are signals centered at 0 V. In this case, as shown in FIG. 10A, signals S4+ and 4− are signals centered at 0 V. As shown in FIG. 10B, the voltage (S4+)-(S4−) that is applied to the electrode 24 of the piezoelectric element 21 with respect to the electrode 23 is a signal centered at 0 V. As a result, the piezoelectric body 22 of the piezoelectric element 21 may be depolarized. Even if depolarization does not occur, a polarization state of the piezoelectric body 22 may be adversely affected.

### Second Comparative Example

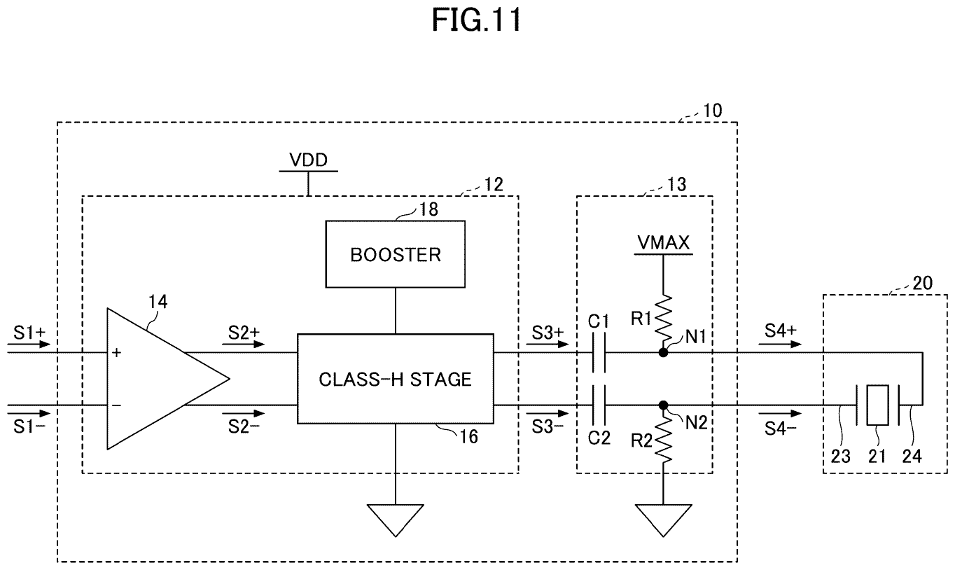

FIG. 11 is a block diagram of the drive circuit in a second comparative example. In the second comparative example, a voltage VMAX that has a maximum value of the output signals S3+ and S3− of the class-H stage 16 is prepared. The voltage at the node N1 is pulled up to the voltage VMAX via the resistor R1, and the voltage at the node N2 is pulled down to 0 V via the resistor R2.

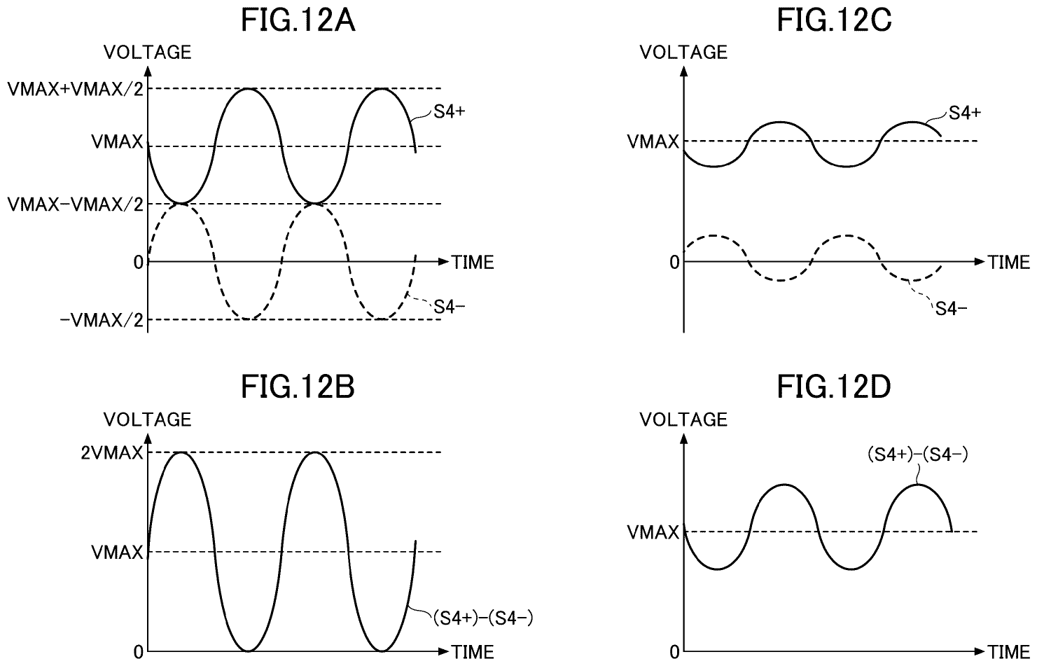

FIGS. 12A to 12D are diagrams showing the voltages with respect to time in the second comparative example. Table 1 shows the signals S4+, S4−, and (S4+)-(S4−) when the signal S2+ is at a minimum, midpoint, and maximum.

TABLE 1

| | | S2 AT | |
|---|---|---|---|
| | S2 AT MINIMUM | MIDPOINT | S2 AT MAXIMUM |
| S4+ | VMAX − VMAX/2 | VMAX | VMAX + VMAX/2 |
| S4− | VMAX/2 | 0 | −VMAX/2 |
| (S4+) − (S4−) | 0 | VMAX | 2VMAX |

As shown in FIG. 12A, the signal S4+ is pulled up by the voltage VMAX, and the signal S4+ becomes a signal centered at the voltage VMAX. The signal S4− is pulled down by 0 V, and the signal S4− becomes a signal centered at the voltage 0 V. As shown in Table 1, the signal S4+ becomes VMAX−VMAX/2, VMAX, and VMAX+VMAX/2 when the signal S2+ is at the minimum, midpoint, and maximum, respectively. The signal S4− becomes-VMAX/2, 0 V, and VMAX/2 when the signal S2+ is at the minimum, midpoint, and maximum, respectively.

As shown in FIG. 12B, the signal (S4+)-(S4−) that is supplied to the piezoelectric element 21 is centered at the voltage VMAX. As shown in Table 1, the signal (S4+)-(S4−) becomes 0 V, VMAX, and 2VMAX when the signal S2+ is at the minimum, midpoint, and maximum, respectively. In this arrangement, the voltage at the electrode 24 does not become negative with respect to the electrode 23 of the piezoelectric element 21. As a result, depolarization or adverse effects of the piezoelectric body 22 can be suppressed.

As shown in FIG. 12C, even when the amplitudes of the signals S4+ and S4− are small, the signal S4+ becomes a signal centered at the voltage VMAX. The signal S4− becomes a signal centered at 0 V.

As shown in FIG. 12D, the signal (S4+)-(S4−) supplied to the piezoelectric element 21 becomes a signal centered at the voltage VMAX. In this case, a voltage of about the voltage VMAX is constantly applied to the piezoelectric element 21, and current flows. This results in large power consumption. In addition, a voltage generation circuit that supplies the voltage VMAX needs to be provided, and thus the drive circuit 10 becomes larger.

### Second Embodiment

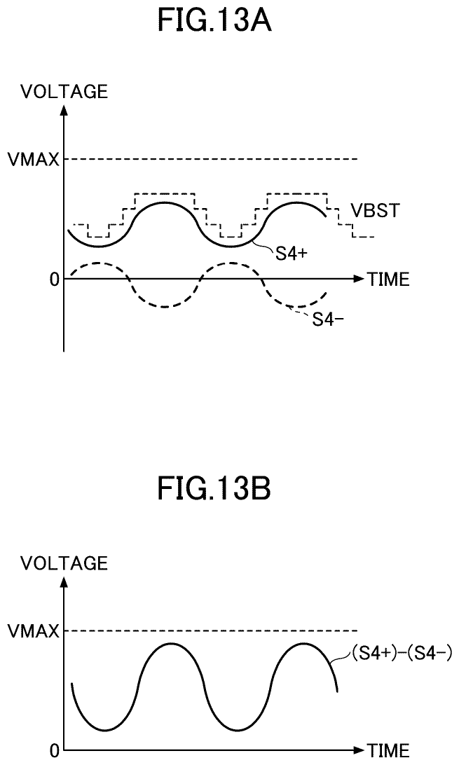

FIGS. 13A and 13B are diagrams showing the voltages with respect to time in the second embodiment. Table 2 shows the signals S4+, S4−, and (S4+)-(S4−) when the signal S2+ is at the minimum, midpoint, and maximum.

TABLE 2

| | | S2 AT | |
|---|---|---|---|
| | S2 AT MINIMUM | MIDPOINT | S2 AT MAXIMUM |
| S4+ | VBST − VBST/2 | VBST | VBST + VBST/2 |
| S4− | VBST/2 | 0 | −VBST/2 |
| (S4+) − (S4−) | 0 | VBST | 2VBST |

When the amplitudes of the signals S4+ and S4− are at maximum values, the voltage VBST is the voltage VMAX, which is the same as in FIG. 12A in the first comparative example.

As shown in FIG. 13A, the voltage VBST varies according to the waveforms of the signals S4+ and S4−. In this case, when the amplitudes of the signals S2+ and S2− are small, the voltage of the signal S4+ becomes lower than the voltage VMAX. The voltage VBST is equal to or higher than the voltage of the signal S4+ at any time point. As a result, as shown in Table 2, the signal S4+ becomes VBST−VBST/2, VBST, and VBST+VBST/2 when the signal S2+ is at the minimum, midpoint, and maximum, respectively. The signal S4− becomes-VBST/2, OV, and VBST/2 when the signal S2+ is at the minimum, midpoint, and maximum, respectively.

As shown in FIG. 13B, the signal (S4+)-(S4−) is a positive voltage, and the voltage of the signal (S4+)-(S4−) is lower than the voltage VMAX. In this case, a voltage lower than the voltage VMAX is applied to the piezoelectric element 21. As a result, power consumption can be reduced compared to the second comparative example. Moreover, since the voltage VBST used in the class-H stage 16 is utilized, there is no need to provide a voltage generation circuit that supplies the voltage VBST. In this arrangement, the drive circuit 10 can be made compact.

According to the second embodiment, the pull-up circuit 13 pulls up the signal S3+ to a pull-up voltage VBST whose voltage value is changed based on the voltage of the input signal S2+, and then the pull-up circuit 13 supplies a pulled-up drive signal S4+ to the piezoelectric element 21. In this arrangement, since the voltage VBST can be lower than the voltage VMAX in the second comparative example, the current flowing through the piezoelectric element 21 can be suppressed, and power consumption can be suppressed.

The booster 18 may generate the voltage VBST based on the voltage of the current signal S2+, or may generate the voltage VBST based on the voltage of the past signal S2+. The booster 18 may generate the voltage VBST based on the envelope of the signal S2+.

The pull-up voltage VBST is the power supply voltage for the class-H stage 16. In this arrangement, it is not necessary to provide a generation circuit that generates the pull-up voltage VBST, and thus the drive circuit 10 can be made compact. A class-G or the class-H amplifier is known as such an amplifier.

In the pull-up circuit 13, the resistor R1 need not be used to pull-up the voltage at the node N1, and the resistor R2 need not be used to pull-up the voltage at the node N2. The voltage at the node N1 may be pulled up to VDD, and the voltage at the node N2 may be pulled down to a voltage higher than 0 V. In this case, if the signal S3 is defined as (S3+)-(S3−) and the signal S4 is defined as (S4+)-(S4−), the signal S3 is pulled up to the pull-up voltage, and the pulled-up drive signal S4 is supplied to the piezoelectric element 21. The amplifier 12 may output the signal S3 with respect to ground instead of a differential output, and the electrode 23 may be grounded.

### Third Embodiment

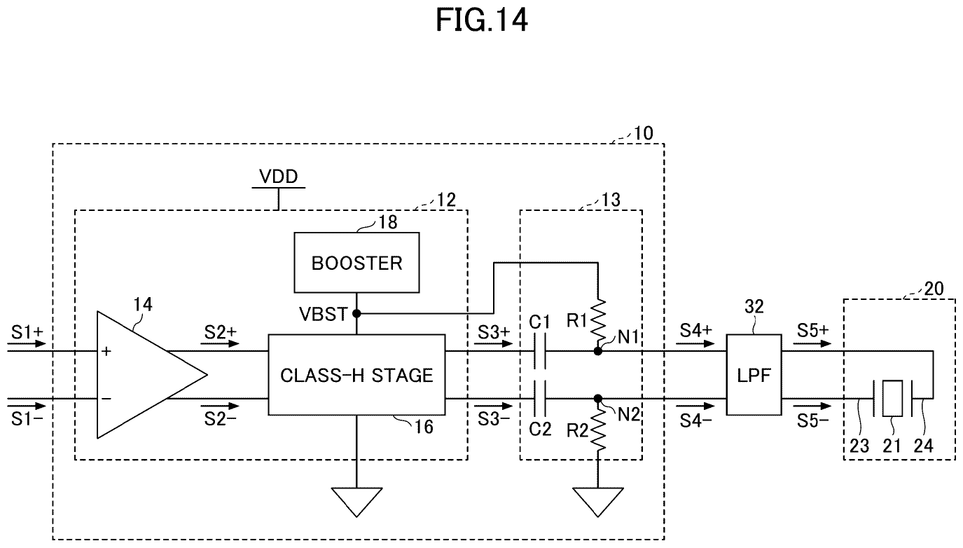

FIG. 14 is a block of the drive circuit according to a third embodiment. As shown in FIG. 14, a drive circuit 10 is connected to a low pass filter (LPF) 32. Among signals S4+ and S4− output from the pull-up circuit 13, the LPF 32 suppresses a high frequency component, and passes a low frequency component. The signal that is passed through the LPF 32 is supplied to the piezoelectric element 21 of the MEMS speaker 20. The LPF 32 is an analog filter. Other configurations are the same as in the first embodiment, and description thereof is omitted.

Since the piezoelectric element 21 has a large capacitive component, the impedance of the piezoelectric element 21 decreases as the frequency increases. In this arrangement, if the signal supplied to the piezoelectric element 21 includes a high-frequency component, power consumption is increased.

High-frequency sounds of 16 kHz or higher are hardly audible to humans, but high-frequency sounds with high intensity may have an adverse effect on hearing. As an example, the International Non-Ionizing Radiation Committee (INIRC) has specified that the sound pressure associated with frequency occupational exposure to sound waves with frequencies of 16 kHz to 20 KHz is 70 dB or less, and that a sound pressure limit for ultrasonic sound pressure with frequencies of 20 kHz to 100 kHz is 100 dB or less. The output of the sound waves of the MEMS speaker 20 is flat up to the high-frequency range. In this case, when the signals of 16 kHz or higher are input to the MEMS speaker 20, the MEMS speaker 20 outputs sound waves or ultrasonic waves of 16 kHz or higher. This may adversely affect human hearing.

Therefore, in the third embodiment, the LPF 32 passes the frequency components of the audible range of the signals S4+ and S4−, and suppresses the frequency components that are higher than the audible range. In this arrangement, signals S5+ and S5− having the frequency components of ultrasonic waves that exceed a human audible range can be suppressed from being input to the MEMS speaker 20. As a result, power consumption of the MEMS speaker 20 can be suppressed. The frequencies of the audible range are higher than or equal to 20 Hz and lower than or equal to 20 kHz. The frequency components of ultrasonic waves are 20 kHz or higher.

A cutoff frequency of the LPF 32 is preferably higher than or equal to 10 kHz and lower than or equal to 20 kHz. In this arrangement, the signals S5+ and S5− having frequency components of high-frequency sound that is hardly audible to humans can be suppressed from being input to the MEMS speaker 20. As a result, power consumption of the MEMS speaker 20 can be suppressed. Also, sound pressure of the sound waves that may adversely affect human hearing can be suppressed.

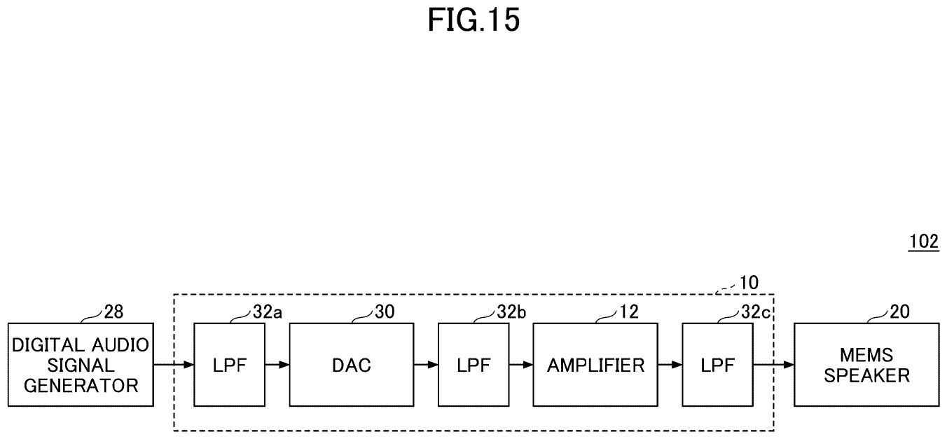

FIG. 15 is a block diagram of the electro-acoustic conversion system according to the third embodiment. An LPF 32a filters the signal output from the digital audio signal generator 28, and outputs the filtered signal to the DAC 30. The LPF 32a is a digital filter. The LPF 32a may be provided in the digital audio signal generator 28. In this case, it is not necessary to provide the LPF after the digital audio signal generator 28, and thus the number of components can be reduced.

An LPF 32b filters the signal output from the DAC 30, and outputs the filtered signal to the amplifier 12. An LPF 32c filters the signal output from the amplifier 12, and outputs the filtered signal to the MEMS speaker 20. By providing the LPF 32c after the amplifier 12, it is possible to eliminate a high frequency component that is derived from noise caused by the amplifier 12.

The drive circuit 10 may include at least one of the LPF 32a, the LPF 32b, or the LPF 32c. When the drive circuit 10 includes the LPF 32a, the DAC 30 may be included in the drive circuit 10.

Although the embodiments have been described above, the above embodiments are presented by way of examples, and the present disclosure is not limited to the above embodiments. The above embodiments can be embodied in a variety of other forms. Various combinations, omissions, substitutions, and changes can be made without departing from the gist of the disclosure. These embodiments and their equivalents are intended to cover such forms or modifications.

What is claimed is:

1. A drive circuit comprising:
an amplifier configured to amplify an input signal, and supply the amplified input signal as a drive signal to a piezoelectric element of a MEMS (Miro-Electro-Mechanical Systems) speaker driven by the piezoelectric element; and
an offset generator configured to generate an offset such that a minimum absolute value of a voltage of the drive signal is greater than or equal to a positive predetermined voltage.

2. The drive circuit according to claim 1, wherein the piezoelectric element includes a piezoelectric body, a first electrode, and a second electrode, the first electrode and the second electrode being configured to apply the voltage to the piezoelectric body, and
wherein the drive signal is configured to be supplied to the piezoelectric element such that the second electrode is at a positive voltage with respect to the first electrode.

3. The drive circuit according to claim 2, wherein the piezoelectric body is configured to be spontaneously polarized in a positive direction from the first electrode toward the second electrode.

4. The drive circuit according to claim 1, wherein the offset generator is configured to add the offset to the drive signal after amplification by the amplifier.

5. The drive circuit according to claim 1, wherein the offset generator is configured to add the offset to the input signal before amplification by the amplifier.

6. The drive circuit according to claim 1, further comprising:
a digital-to-analog converter configured to convert a digital signal into the input signal that is an analog signal,
wherein the offset generator is configured to add the offset to the digital signal.

7. An electro-acoustic conversion system comprising:
the drive circuit of claim 1; and
the MEMS speaker.

8. A drive circuit comprising:
an amplifier configured to amplify an input signal, and output the amplified input signal as an output signal; and
a pull-up circuit configured to pull up the output signal to a pull-up voltage whose voltage value is changed based on a voltage waveform of the input signal, and supply the pulled-up output signal as a drive signal to a piezoelectric element of a MEMS (Miro-Electro-Mechanical Systems) speaker driven by the piezoelectric element.

9. The drive circuit according to claim 8, wherein the pull-up voltage when a voltage of the output signal is at a first voltage is lower than the pull-up voltage when the voltage of the output signal is at a second voltage higher than the first voltage.

10. The drive circuit according to claim 9, wherein in the voltage waveform of the output signal, the pull-up voltage when the voltage of the output signal is at the first voltage is lower than or equal to a maximum voltage and higher than or equal to the first voltage.

11. The drive circuit according to claim 8, wherein a power supply voltage for the amplifier is configured to be set based on the voltage waveform of the input signal, and
wherein the pull-up voltage is the power supply voltage.

12. The drive circuit according to claim 11, wherein the amplifier includes a class-G amplifier or a class-H amplifier.

13. The drive circuit according to claim 8, further comprising:
a low-pass filter configured to pass a frequency component within an audible range of the drive signal, and suppress a frequency component higher than the audible range.

14. The drive circuit according to claim 8, wherein the piezoelectric element includes a piezoelectric body, a first electrode, and a second electrode, the first electrode and the second electrode being configured to apply a voltage to the piezoelectric body, and
wherein the drive signal is configured to be supplied to the piezoelectric element such that the second electrode is at a positive voltage with respect to the first electrode.

15. The drive circuit according to claim 14, wherein the piezoelectric body is configured to be spontaneously polarized in a positive direction from the first electrode toward the second electrode.

16. An electro-acoustic conversion system comprising:
the drive circuit of claim 8; and
the MEMS speaker.
